(19) United States
(12) Patent Application Publication
(10) Pub. No.: US 2007/0247250 A1
(43) Pub. Date: Oct. 25, 2007

(54) Apparatus and method presenting a clock signal in response to receiving a drive signal

(76) Inventors: Stewart S. Taylor, Beaverton, OR (US); Jing-Hong C. Zhan, Hillsboro, OR (US)

Correspondence Address: LAW OFFICE OF DONALD D. MONDUL;c/o INTELLEVATE, P.O. BOX 52050, MINNEAPOLIS, MN, 55402, US

(21) Appl. No.: 11/392,159

(22) Filed: Mar. 29, 2006

(51) Int. Cl. H03L 7/099

(52) U.S. Cl. 331/185

(57) ABSTRACT

An apparatus presents a clock signal in response to receiving a drive signal. The clock signal has a clock amplitude established independent of the drive signal. The apparatus includes: (a) A drive section coupled for receiving the drive signal. The drive section presents the clock signal at a clock locus in response to the drive signal. (b) An operating signal source coupled with the drive section. The operating signal source provides a supply signal to the drive section. The drive section employs the supply signal to establish the clock amplitude.

### BACKGROUND

A capability to implement a precision amplitude clock signal is desirable for a variety of systems. Such a capability is very important regarding amplitude for signals from a local oscillator (LO). Local oscillators may be used, by way of example and not by way of limitation, for driving passive mixers in high-performance radios. There is an optimum clock signal amplitude which balances linearity against noise figure (NF). If clock signal amplitude is too large, linearity suffers. If clock signal amplitude is too small, NF suffers. Too large a clock signal amplitude may also increase power required to operate the circuitry using the clock signal, or increase power required to generate the clock signal or increase power used in both operations. There is also an optimum clock signal amplitude to balance broadband noise against flicker noise. Larger signal swings typically improve broadband noise while degrading flicker noise. Therefore, there is an optimum clock signal amplitude to produce the best NF and linearity, depending upon the standard or application of the system employing the clock signal. Optimum clock signal amplitude is generally not the full power supply voltage. It is the full power supply voltage which is typically provided in prior art systems using digital inverters. There is a need for a circuit or apparatus to produce a desired optimum clock signal amplitude. There is also a need for a circuit or apparatus to measurably control the provision of an optimum clock signal amplitude in a device or apparatus using the clock signal.

### BRIEF DESCRIPTION OF THE DRAWINGS

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings in which:

FIG. 1 is an electrical schematic diagram illustrating; a first embodiment of the present invention;

FIG. 2 is a schematic diagram illustrating a second embodiment of the present invention at a system level;

FIG. 3 is a schematic diagram of a representative application of the second embodiment of the present invention; and

FIG. 4 is a flow chart illustrating the method of the present invention.

It will be appreciated that for simplicity and clarity of illustration, elements illustrated in the figures have not necessarily been drawn to scale. For example, the dimensions of some of the elements are exaggerated relative to other elements for clarity. Further, where considered appropriate, reference numerals have been repeated among the figures to indicate corresponding or analogous elements.

### DETAILED DESCRIPTION

In the following detailed description, numerous specific details are set forth in order to provide a thorough understanding of the invention. However, it will be understood by those skilled in the art that the present invention may be practiced without these specific details. In other instances, well-known methods, procedures, components and circuits have not been described in detail so as not to obscure the present invention.

Embodiments of the present invention may include apparatuses for performing the operations herein. An apparatus may be specially constructed for the desired purposes, or it may comprise a general purpose computing device selectively activated or reconfigured by a program stored in the device. Such a program may be stored on a storage medium, such as, but not limited to, any type of disk including floppy disks, optical disks, compact disc read only memories (CD-ROMs), magnetic-optical disks, read-only memories (ROMs), random access memories (RAMs), electrically programmable read-only memories (EPROMs), electrically erasable and programmable read only memories (EEPROMs), magnetic or optical cards, or any other type of media suitable for storing electronic instructions, and capable of being coupled to a system bus for a computing device.

The processes and displays presented herein are not inherently related to any particular computing device or other apparatus. Various general purpose systems may be used with programs in accordance with the teachings herein, or it may prove convenient to construct a more specialized apparatus to perform the desired method. The desired structure for a variety of these systems will appear from the description below. In addition, embodiments of the present invention are not described with reference to any particular programming language. It will be appreciated that a variety of programming languages may be used to implement the teachings of the invention as described herein. In addition, it should be understood that operations, capabilities, and features described herein may be implemented with any combination of hardware (discrete or integrated circuits) and software.

Use of the terms “coupled” and “connected”, along with their derivatives, may be used. It should be understood that these terms are not intended as synonyms for each other. Rather, in particular embodiments, “connected” may be used to indicate that two or more elements are in direct physical or electrical contact with each other. “Coupled” my be used to indicated that two or more elements are in either direct or indirect (with other intervening elements between them) physical or electrical contact with each other, and/or that the two or more elements co-operate or interact with each other (e.g. as in a cause an effect relationship).

It should be understood that embodiments of the present invention may be used in a variety of applications. Although the present invention is not limited in this respect, the devices disclosed herein may be used in many apparatuses such as in the transmitters and receivers of a radio system. Radio systems intended to be included within the scope of the present invention include, by way of example only, cellular radiotelephone communication systems, satellite communication systems, two-way radio communication systems, one-way pagers, two-way pagers, personal communication systems (PCS), personal digital assistants (PDA's), wireless local area networks (WLAN), personal area networks (PAN), metropolitan area network (MAN), broadband wireless networks and the like.

Types of cellular radiotelephone communication systems intended to be within the scope of the present invention include, although not limited to, Code Division Multiple Access (CDMA) cellular radiotelephone communication systems, Global System for Mobile Communications (GSM) cellular radiotelephone systems, North American Digital Cellular (NADC) cellular radiotelephone systems, Time Division Multiple Access (TDMA) systems, Extended-TDMA (E-TDMA) cellular radiotelephone systems, third generation (3G) systems like Wide-band CDMA (WCDMA), CDMA-2000, worldwide interoperability for microwave access (WiMAX) wireless systems, Orthogonal Frequency Division Multiplexing Access (OFDMA) systems and the like.

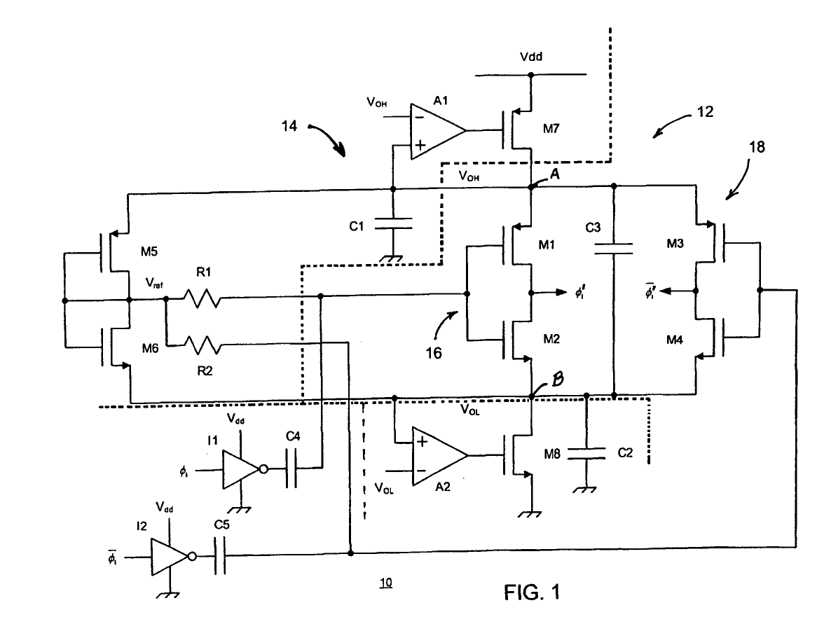

FIG. 1 is an electrical schematic diagram illustrating; a first embodiment of the present invention. In FIG. 1, an apparatus 10 may include a drive section 12 and a supply voltage source 14, generally indicated in sections separated by broken lines in FIG. 1. Drive section 12 may also be referred to as an inverter section 12. Drive section 12 may include an inverter I1 receiving a drive signal φ₁ and an inverter I2 receiving a drive signal φ̅₁. Complementary input signals φ₁, φ̅₁ may be substantially equal in amplitude and opposite in phase; that is, signals φ₁, φ̅₁ may be substantially fully differential signals. A capacitor C4 AC (alternating current) may couple inverter I1 with an inverter circuit 16 to provide a gating signal to inverter circuit 16. Inverter circuit 16 may include transistors M1, M2. A capacitor C5 AC may couple inverter I2 with an inverter circuit 18 to provide a gating signal to inverter circuit 18. Inverter circuit 18 may include transistors M3, M4.

Supply voltage source 14 may include transistors M5, M6 coupled to receive input signals from inverters I1, I2 via AC (alternating current) coupling capacitors C4, C5 and isolating resistors R1, R2. Transistors M5, M6 may cooperate with resistors R1, R2 to establish a reference voltage V_{REF}. An amplifier A1, a filter capacitor C1 and a regulating transistor M7 may cooperate to establish an upper regulated voltage V_{OH} for inverter circuits 16, 18. An amplifier A2, a filter capacitor C2 and a regulating transistor M8 may cooperate to establish a lower regulated voltage V_{OL} for inverter circuits 16, 18.

Transistors M1, M2, M3, M4 may be powered from two internally regulated voltages, V_{OH}, V_{OL}. Regulated voltages V_{OH}, V_{OL} may fall within the power supply voltage rails V_{dd} and ground and may be applied to loci A, B in FIG. 1. Output signals φ′₁, φ̅′₁ from inverters 16, 18 may be provided as clock signals to a device, such as by way of example and not by way of limitation a mixer device for a radio apparatus. Output clock signals φ′₁, φ̅′₁ may each have an amplitude range between regulated voltages V_{OH}. V_{OL}. Regulated voltages V_{OH}, V_{OL} may be established independent of input signals φ₁, φ̅₁. Input signals φ₁, φ̅₁ may be regarded as drive signals which determine the period or phase of output clock signals φ′₁, φ̅′₁. Output clock signals φ′₁, φ̅′₁ may thus be complementary signals that are substantially equal in amplitude and opposite in phase; that is, output signals φ′₁, φ̅′₁ may be substantially fully differential signals. The amplitude of each of output signals φ′₁, φ̅′₁ may be determined by regulated voltages V_{OH}, V_{OL}, and regulated voltages V_{OH}, V_{OL} may be established by supply voltage source 14.

An optional filter capacitor C3 may be used to further stabilize the amplitude signal swing of output signals φ′₁, φ̅′₁ between voltages V_{OH}, V_{OL}. In apparatus 10 the DC (direct current) bias of transistors M1, M2 and transistors M3, M4 may be set by reference voltage V_{REF}. Reference voltage V_{REF} may be produced by transistors M5, M6 and isolating resistors R1, R2.

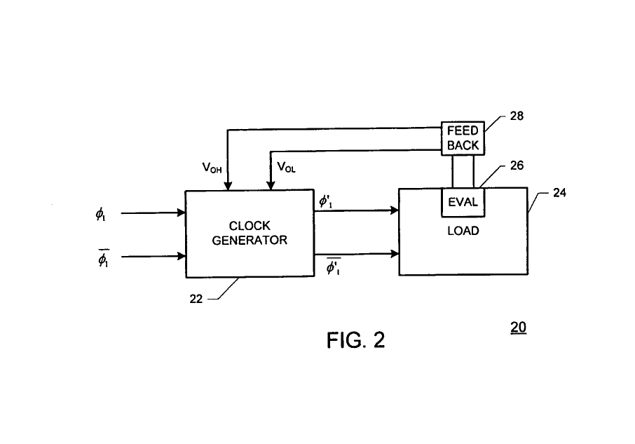

In FIG. 1, apparatus 10 may produce regulated voltages V_{OH}, V_{OL} on-chip from supply voltage source 14. A preferred embodiment of apparatus 10 may configure drive section 12 and supply voltage source 14 as an integral structure in a single unit. In another embodiment of the present invention, regulated voltages V_{OH}. V_{OL} may be controlled by the device to which output signals φ′₁, φ̅′₁ may be provided for use as clock signals, as illustrated in FIG. 2.

FIG. 2 is a schematic diagram illustrating a second embodiment of the present invention at a system level. In FIG. 2, a system 20 may include a clock generator unit 22 and a load device 24. Clock generator unit 22 may be configured generally as described in connection with drive section 12 (FIG. 1). Clock generator unit may receive input signals φ₁, φ̅₁ and may present output signals φ′₁, φ̅′₁ for use by load device 24. Load device 24 may include an evaluating unit 26. Evaluating unit 26 may effect evaluation of at least one operating parameter of load device 24 such as, by way of example and not by way of limitation, bit error rate (BER), sensitivity, signal-to-noise ratio (SN), noise figure (NF), flicker noise or another operating parameter. A feedback unit 28 may operate to provide regulated voltages V_{OH}, V_{OL} to clock generator unit 22. Regulated voltages V_{OH}. V_{OL} may be received, by way of example and not by way of limitation, at loci such as loci A, B in apparatus 10 (FIG. 1).

As described hereinabove in connection with apparatus 10 (FIG. 1) output clock signals φ′₁, φ̅′₁ may each have an amplitude range between regulated voltages V_{OH}, V_{OL}. Regulated voltages V_{OH}, V_{OL} may be established independent of input signals φ₁, φ̅₁. Input signals φ₁, φ̅₁ may be regarded as drive signals which determine the period or phase of output clock signals φ′₁, φ̅′₁. Output clock signals φ′₁, φ̅′₁ may thus be complementary signals that are substantially equal in amplitude and opposite in phase; that is, output signals φ′₁, φ̅′₁ may be substantially fully differential signals. The amplitude of each of output signals φ′₁, φ̅′₁ may be determined by regulated voltages V_{OH}, V_{OL}, and regulated voltages V_{OH}, V_{OL} may be established by evaluating unit 26 in cooperation with feedback unit 28. Regulated voltages V_{OH}, V_{OL} may be regulated by evaluating unit 26 in cooperation with feedback unit 28 to improve the at least one operating parameter that is evaluated by evaluating unit 26. Amplitude of output signals φ′₁, φ̅′₁ may be optimally adaptively controlled for best circuit performance by load device 24. If desired, feedback unit 28 may be combined with evaluating unit 26 into a single evaluating unit 26.

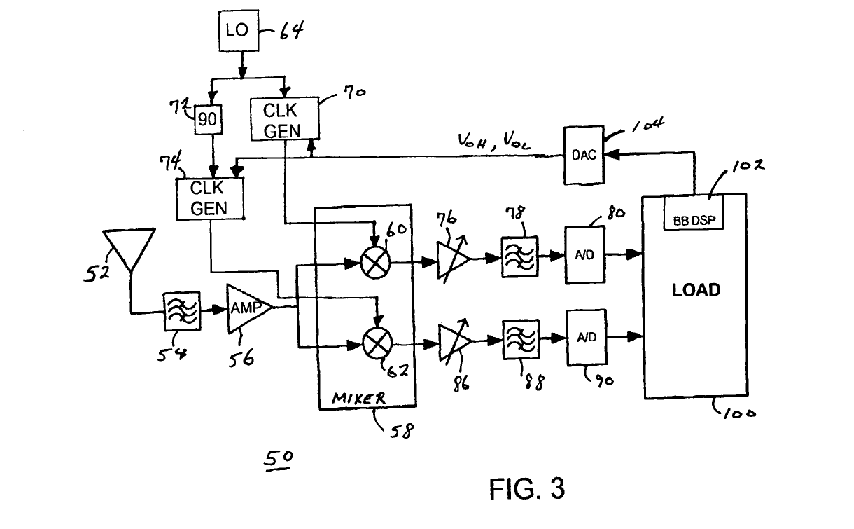

FIG. 3 is a schematic diagram of a representative application of the second embodiment of the present invention. In FIG. 3, a radio apparatus 50 may include a receiving antenna 52, a signal filter 54 and an amplifier 56 for delivering a received signal to a mixer unit 58. Amplifier 56 may deliver the received signal to a first mixer device 60 and a second mixer device 62 in mixer unit 58. A local oscillator 64 may present a signal to a first clock generator 70 and to a 90 degree phase shifter 72. Phase shifter 72 may present a shifted signal to a second clock generator 74. Clock generators 70, 74 may be configured as described in connection with drive section 12 (FIG. 1) and clock generator 22 (FIG. 2). First clock generator 70 may present a non-shifted mixing signal to mixer device 60. Mixer device 60 may mix the non-shifted mixing signal from first clock generator 70 with the signal received from amplifier 56 to present a first mixed signal to a first gain amplifier 76. A signal output from first gain amplifier 76 may be filtered by a low pass filter 78, treated by an analog-to-digital converter 80 and presented for use by a load 100. Second clock generator 74 may present a shifted mixing signal to mixer device 62. Mixer device 62 may mix the shifted mixing signal from second clock generator 74 with the signal received from amplifier 56 to present a second mixed signal to a second gain amplifier 86. A signal output from second gain amplifier 86 may be filtered by a low pass filter 88, treated by an analog-to-digital converter 90 and presented for use by a load 100.

Load 100 may include an evaluating unit 102. By way of example and not by way of limitation, evaluating unit 102 may be embodied in a baseband digital signal processor (BB DSP), as indicated in FIG. 3. Evaluating unit 102 may provide a feedback signal indicating results of an evaluation of input signals received from analog-to-digital converters 80, 90. By way of example and not by way of limitation evaluating unit may perform an evaluation of at least one operating parameter of load 100 such as bit error rate (BER), sensitivity, signal-to-noise ratio (SN), noise figure (NF), flicker noise or another operating parameter.

A digital-to-analog converter 104 may convert signals received from evaluating unit 102 for presentation to clock generators 70, 74. Signals presented from digital-to-analog converter 104 may be regulated voltages V_{OH}. V_{OL} to clock generators 70, 74. Regulated voltages V_{OH}, V_{OL} may be received, by way of example and not by way of limitation, by clock generators 70, 74 at loci such as loci A, B in apparatus 10 (FIG. 1). Regulated voltages V_{OH}, V_{OL} may be regulated by evaluating unit 102 to improve the at least one operating parameter that is evaluated by evaluating unit 102. Amplitude of signals received from analog-to-digital converters 80, 90 may be optimally adaptively controlled for best circuit performance by load 100.

The present invention may permit adaptive control of amplitude of local oscillator signals in order to achieve best circuit performance. The adaptive capability of the present invention may be important because different amplitude swings may be required for different applications. By way of example and not by way of limitation, greater local oscillator amplitude swing may reduce broadband (a signal that exhibits substantial uniformity within a range of frequency) noise but may degrade flicker (1/f) noise. In some applications, such as narrowband GSM (Groupe Speciale Mobile; also, Global System for Mobile communications) mobile communication applications, flicker noise may be critically important and may need to be reduced. In broadband applications, such as WiFi (Wireless Fidelity; a wireless system configured according to an IEEE standard 802.11a/b/g), broadband noise may be more important and more flicker noise may be tolerated. Thus, different local oscillator amplitudes may be required for different applications. The present invention may provide an apparatus and method for controlling local oscillator amplitude swings for various differing applications.

CMOS (Complementary Metal Oxide Semiconductor) inverter local oscillators may be beneficial in that they have very fast edges and can dissipate low power if the frequency of operation is moderate. Source coupled logic, sometimes called current mode logic (CML), may provide controlled amplitude swings in some cases, but often dissipates excessive power. Current mode logic typically may have greater thermal noise and a higher impedance than other technologies. Both thermal noise and higher impedance may degrade radio performance. Additionally, current mode logic may not work for some values of logic swing. The present invention may provide an apparatus and method that permits appropriate control to facilitate use of current mode logic.

Another application of the present invention thermal noise and a higher impedance to provide a clock signal of a sampler in a direct sampling receiver that employs high threshold voltage devices. This application typically may require an offset clock signal that swings outside the digital power supply voltage. The present invention may also provide higher sensitivity and linearity in a mixer, thereby also providing higher sensitivity and linearity in a radio receiver using such a mixer. This improved performance provided by using the present invention in a mixer may eliminate an external low noise amplifier (LNA) in front of some CMOS receivers or reduce power used by the receiver.

The present invention may facilitate implementation of a precision local oscillator drive for mixers and other systems. The present invention may permit implementing high sensitivity communication chip sets in low-cost CMOS technology. The present invention may permit communication and control between an evaluation unit such as a baseband digital signal processor and a radio (using an RF/analog processing unit).

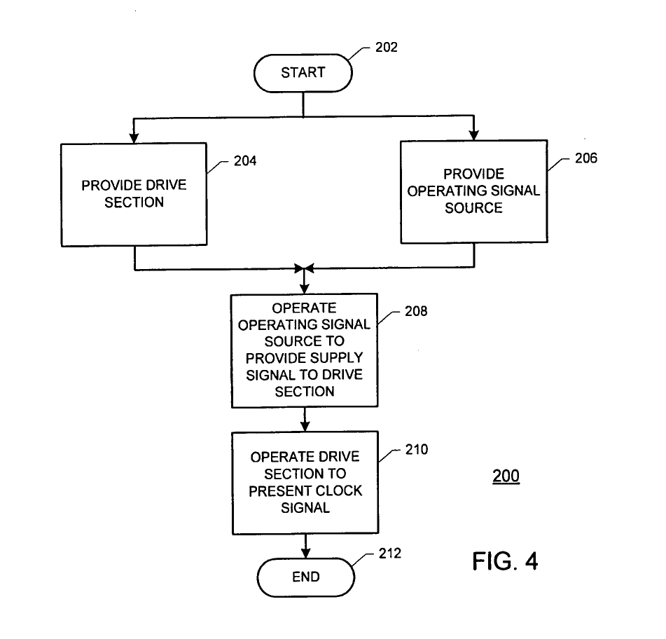

FIG. 4 is a flow chart illustrating the method of the present invention. In FIG. 4, a method 200 presenting a clock signal in response to a received drive signal may begin at a START locus 202. The clock signal may have a clock amplitude established independent of the drive signal. Method 200 may continue with, in no particular order: (1) Providing a drive section coupled for receiving the drive signal, as indicated by a block 204. (2) Providing an operating signal source coupled with the drive section, as indicated by a block 206.

Method 200 may continue with operating the operating signal source to provide a supply signal to the drive section, as indicated by a block 208. Method 200 may continue with operating the drive section to present the clock signal at a clock locus in response to the drive signal, as indicated by a block 210. The drive section may employ the supply signal to establish the clock amplitude. Method 200 may terminate at an END locus 212.

While certain features of the invention have been illustrated and described herein, many modifications, substitutions, changes, and equivalents will now occur to those skilled in the art. It is, therefore, to be understood that the appended claims are intended to cover all such modifications and changes as fall within the true spirit of the invention.

1. An apparatus receiving a first oscillating signal having a first frequency and presenting a second oscillating signal having an amplitude established independent of said first oscillating signal; the apparatus comprising:
(a) an inverter section coupled for receiving said first oscillating signal; said inverter section presenting said second oscillating signal at an output locus in response to said first oscillating signal; and
(b) a supply voltage source coupled with said inverter section; said supply voltage source providing at least one supply voltage to said inverter section; said inverter section using said at least one supply voltage to establish said amplitude of said second oscillating signal.

2. An apparatus receiving a first oscillating signal having a first frequency and presenting a second oscillating signal having an amplitude established independent of said first oscillating signal as recited in claim 1 wherein said second oscillating signal is generally in phase with said first oscillating signal.

3. An apparatus receiving a first oscillating signal having a first frequency and presenting a second oscillating signal having an amplitude established independent of said first oscillating signal as recited in claim 1 wherein said first oscillating signal and said second oscillating signal are each a substantially fully differential signal.

4. An apparatus receiving a first oscillating signal having a first frequency and presenting a second oscillating signal having an amplitude established independent of said first oscillating signal as recited in claim 1 wherein said supply voltage source is integrally included in the apparatus.

5. An apparatus receiving a first oscillating signal having a first frequency and presenting a second oscillating signal having an amplitude established independent of said first oscillating signal as recited in claim 1 wherein the apparatus further comprises a receiving device for using said second oscillating signal, and wherein said supply voltage source is a feedback loop from said receiving device.

6. An apparatus receiving a first oscillating signal having a first frequency and presenting a second oscillating signal having an amplitude established independent of said first oscillating signal as recited in claim 5 wherein said feedback loop includes an evaluating unit for evaluating operation of said receiving device with respect to at least one operating parameter; said evaluating unit altering said at least one supply voltage to improve said operation.

7. An apparatus receiving a first oscillating signal having a first frequency and presenting a second oscillating signal having an amplitude established independent of said first oscillating signal as recited in claim 2 wherein said first oscillating signal and said second oscillating signal are each a substantially fully differential signal.

8. An apparatus receiving a first oscillating signal having a first frequency and presenting a second oscillating signal having an amplitude established independent of said first oscillating signal as recited in claim 2 wherein said supply voltage source is integrally included in the apparatus.

9. An apparatus receiving a first oscillating signal having a first frequency and presenting a second oscillating signal having an amplitude established independent of said first oscillating signal as recited in claim 3 wherein said supply voltage source is integrally included in the apparatus.

10. An apparatus receiving a first oscillating signal having a first frequency and presenting a second oscillating signal having an amplitude established independent of said first oscillating signal as recited in claim 2 wherein the apparatus further comprises a receiving device for using said second oscillating signal, and wherein said supply voltage source is a feedback loop from said receiving device; said feedback loop including an evaluating unit for evaluating operation of said receiving device with respect to at least one operating parameter; said evaluating unit altering said at least one supply voltage to improve said operation.

11. An apparatus receiving a first oscillating signal having a first frequency and presenting a second oscillating signal having an amplitude established independent of said first oscillating signal as recited in claim 3 wherein the apparatus further comprises a receiving device for using said second oscillating signal, and wherein said supply voltage source is a feedback loop from said receiving device; said feedback loop including an evaluating unit for evaluating operation of said receiving device with respect to at least one operating parameter; said evaluating unit altering said at least one supply voltage to improve said operation.

12. An apparatus receiving a first oscillating signal having a first frequency and presenting a second oscillating signal having an amplitude established independent of said first oscillating signal as recited in claim 4 wherein the apparatus further comprises a receiving device for using said second oscillating signal, and wherein said supply voltage source is a feedback loop from said receiving device; said feedback loop including an evaluating unit for evaluating operation of said receiving device with respect to at least one operating parameter; said evaluating unit altering said at least one supply voltage to improve said operation.

13. An apparatus presenting a clock signal in response to receiving a drive signal; said clock signal having a clock amplitude established independent of said drive signal; the apparatus comprising:
(a) a drive section coupled for receiving said drive signal; said drive section presenting said clock signal at a clock locus in response to said drive signal; and
(b) an operating signal source coupled with said drive section; said operating signal source providing a supply signal to said drive section; said drive section employing said supply signal to establish said clock amplitude.

14. An apparatus presenting a clock signal in response to receiving a drive signal as recited in claim 13 wherein said clock signal is generally in phase with said drive signal and wherein said drive signal and said clock signal are each a substantially fully differential signal.

15. An apparatus presenting a clock signal in response to receiving a drive signal as recited in claim 13 wherein said operating signal source is integrally included in the apparatus.

16. An apparatus presenting a clock signal in response to receiving a drive signal as recited in claim 13 wherein the apparatus further comprises a receiving device for using said clock signal, and wherein said operating signal source is a feedback loop from said receiving device; said feedback loop including an evaluating unit for evaluating operation of said receiving device with respect to at least one operating parameter; said evaluating unit altering said at least one supply voltage to improve said operation.

17. An apparatus presenting a clock signal in response to receiving a drive signal as recited in claim 14 wherein said operating signal source is integrally included in the apparatus.

18. An apparatus presenting a clock signal in response to receiving a drive signal as recited in claim 14 wherein the apparatus further comprises a receiving device for using said clock signal, and wherein said operating signal source is a feedback loop from said receiving device; said feedback loop including an evaluating unit for evaluating operation of said receiving device with respect to at least one operating parameter; said evaluating unit altering said at least one supply voltage to improve said operation.

19. A method presenting a clock signal in response to a received drive signal; said clock signal having a clock amplitude established independent of said drive signal; the method comprising:
(a) in no particular order:
(1) providing a drive section coupled for receiving said drive signal; and
(2) providing an operating signal source coupled with said drive section;
(b) operating said operating signal source to provide a supply signal to said drive section; and
(c) operating said drive section to present said clock signal at a clock locus in response to said drive signal; said drive section employing said supply signal to establish said clock amplitude.

20. A method presenting a clock signal in response to a received drive signal as recited in claim 19 wherein said operating signal source is integrally included in a structure with said drive section.

21. A method presenting a clock signal in response to a received drive signal as recited in claim 19 wherein the method further comprises providing a receiving device for using said clock signal; and wherein said operating signal source is a feedback loop from said receiving device; said feedback loop including an evaluating unit for evaluating operation of said receiving device with respect to at least one operating parameter; said evaluating unit altering said at least one supply voltage to improve said operation.
